(19) United States
(12) Patent Application Publication
(10) Pub. No.: US 2025/0079127 A1
(43) Pub. Date: Mar. 6, 2025

(54) DIELECTRIC PLASMA ETCHING USING C2H2F2

(71) Applicant: L'Air Liquide, Société Anonyme pour L'Etude et l'Exploitation des Procédés Georges Claude, Paris (FR)

(72) Inventors: Nathan STAFFORD, Newark, DE (US); Colin JENNINGS, Newark, DE (US); Scott BILTEK, Newark, DE (US); Phong NGUYEN, Newark, DE (US)

(21) Appl. No.: 18/239,041

(22) Filed: Aug. 28, 2023

(51) Int. Cl. H01J 37/32; H01L 21/311

(52) U.S. Cl. CPC H01J 37/32449; H01L 21/31116; H01J 2237/334

(57) ABSTRACT

An etching method for forming a structure by selectively etching one or more dielectric films in a substrate using a patterned mask layer deposited on top of the one or more dielectric films comprises mounting the substrate in a reaction chamber, introducing an etching gas containing C₂H₂F₂ into the reaction chamber, converting the etching gas to a plasma, and allowing an etching reaction to proceed between the plasma and the one or more dielectric films so that the one or more dielectric films are selectively etched versus the patterned mask layer to form the structure.

### TECHNICAL FIELD

The present invention relates to a method of plasma etching dielectric materials using a hydrofluorocarbon etching gas C₂H₂F₂ to manufacture semiconductor chips, such as back-end-of-line (BEOL) interconnects (trench and via etch) for logic devices.

### BACKGROUND

Traditional plasma etching gases to manufacture semiconductor devices are commonly fluorocarbon or hydrofluorocarbon gases used to etch silicon-containing materials such as SiO₂, SiN, SiOCH, etc. However, fluorocarbon and hydrofluorocarbon gases used often have high Global Warming Potential (GWP). Table 1 includes the GWP of commonly used etching gases in the semiconductor industry along with other molecules that may be plasma byproducts as well as other chemistries. A traditional etching gas used for etching back end of line (BEOL) dielectric materials such as low-k films are CF₄ or CHF₃ but other fluorocarbon gases can be used for SiO dielectric etching including C₄F₈ or CH₂F₂. As can be seen from the table the GWP of CF₄ (6630) and CHF₃ (12400) is extremely high. As such these molecules are detrimental to the issue of Global Warming. Other fluorocarbons or hydrofluorocarbons commonly used can include CH₂F₂, CH₃F, C₄F₈, C₄F₆, C₂F₆, C₃F₈, etc. Additionally, byproducts from the etch may include NO₂, CO, CO₂, COF₄, SiF₄, etc.

TABLE 1

| Gas | GWP₁₀₀ |
|---|---|
| CHF₃ | 12400 |
| C₂F₆ | 11100 |
| C₄F₈ | 9540 |
| CF₄ | 6630 |
| CH₂F₂ | 677 |
| NO₂ | 265 |
| CO | 2.1 |
| CO₂ | 1 |
| COF₂ | <1 |
| CF₃I | <1 |
| C₄F₆ | <1 |
| C₂H₂F₂ | <1 |

However, the principle of plasma etch is that the molecule fragments thanks to the energy of the plasma and collisions, breaking bonds, creating byproducts, etching the substrate, creating reaction byproducts, and as well recombination of fragments to form new species. Thus, the plasma fragmentation and chemistry is extremely complex and difficult to predict. As such while a molecule that enters the plasma may itself have a high GWP but depending on the fragmentation of that molecule and resulting recombination species and byproducts will determine the GWP of the emissions out of the plasma etch equipment. As the gases exit the plasma etch tool they flow through a vacuum pump, are diluted with nitrogen and generally may pass through to a scrubbing device. The scrubber is generally of two types. The first is a plasma device that further breaks down the molecule. The second is a burner that burns the emissions usually by adding something like methane. Both scrubber types break down the etch byproducts. The plasma device uses energy in a RF while the burner uses thermal energy. Further abatement may occur using wet or dry scrubbers to remove species like HF or other toxic materials. The challenge is that the C—F bond is very strong and difficult to abate. Therefore, while it is important to use etching gases with lower GWPs it is also important to have the emission gases to also have lower GWPs. This is especially true for lower plasma power processes such as BEOL dielectric etching where the lower source power of the etching tool may not completely break down the incoming molecule. Therefore if the incoming etching molecule is high GWP there will be a high proportion of gas exiting the chamber not dissociated and will thus have high GWP emissions or high CO₂ equivalent emissions.

SiO and SiOCH materials are used as insulating films in the manufacturing of semiconductor chips. A variety of compositions of SiO and SiOCH films (often containing other elements such as N, H and B) are used. The etching properties of SiOCH films is often similar to SiO films using fluorocarbon etching gases. The masks used in patterning processes can also vary. For example films like TiN, carbon (amorphous or spin on carbon) and SiN are often used as mask materials when etching SiO and SiOCH films. Selectivity of etching the SiO/SiOCH vs the mask material is critically important. Selectivity is controlled using the fluorocarbon polymer to protect the surface and the sidewall of the pattern structure during etching. The polymer formation is controlled using an etchant such as O₂, N₂, or Ar which can chemically or physically remove the polymer in a variety of ways. The polymer is formed by the fragmentation of the etching molecule in the plasma forming a variety of radical structures which recombine on the surface and form a polymeric material. Etching of the silicon material comes primarily from F-species to form volatile SiF₄. The polymer plays a critical role to protect the surface from the bombardment of ions from the plasma as well as from chemical attack while also providing the F* to etch the Si. The chemical structure is critical to form different species in the plasma that drives the formation of polymer and the etching species and will also impact the GWP of the emissions from the plasma etcher.

Thus the chemical structure is both critical for the etching performance as well as the global warming impact, both the GWP of the molecule and the GWP of the emissions from the process. It is difficult to predict the etching performance as well as the emitted species of a fluorocarbon molecule.

US20160118266 discloses a method for fabricating a semiconductor device that comprises forming a first etching layer and a second etching layer stacked on a substrate, and forming a recess region by etching the first and second etching layers under plasma. The etching gas including a compound is represented by Formula I or II. The compound include at least one of 1,1,1,2,3,3-hexafluoropropane, 2,2,2-trifluoroethane-1-thiol, 1,1,1,3,3-pentafluoropropane, 1,1,2,2,3-pentafluoropropane and 1,1,2,2-tetrafluoro-1-iodoethane, 2,3,3,3-tetrafluoropropene and 1,1-difluoroethene, which does include the use of C₂H₂F₂ in a plasma etching process.

US2020234962 discloses a dry etching gas composition contains a saturated or unsaturated hydrofluorocarbon compound (excluding 1,2,2,3-pentafluorocyclobutane and 1,1,2,2-tetrafluorocyclobutane) represented by a general formula (1): CₓH_{y}F_{z}, where x, y, and z are integers that satisfy 2≤x≤4, y+z≤2x+2, and 0.5<z/y<2. C₂H₂F₂ is listed in the examples among many different molecules along with using an oxidizer in the recipe.

KR970023632 discloses a polymer pattern formation method according to a polymer deposition, in which a reaction gas for forming a polymer of carbon, C₄F₈, CHF₃, CF₄, C₂F₄, C₂F₆, C₂F₆ with a gas containing HBr CCl₄, C₂H₂F₂ and C₂HF₅, uses one of BCl3 gas characterized in that the pattern forming method according to polymer deposition. KR970023632 discloses C₂H₂F₂ among other gases that includes CHF₃ which it has been known a poor performing etchant with high GWP. It also includes the addition of other gases like BCl3 or HBr.

U.S. Pat. No. 5,814,563 discloses a method for etching dielectrics and etching other films like TiN. A composition contains C₂H₂F₂, an etchant like CF₄, N-containing gas like NH₃, and oxidizer like CO, and/or Ar is used for sputtering. The NH₃-generating gas is a gas capable of generating NH₃-containing species such as gases comprising NH₂, NH₃, or NH₄⁺, ions or molecules, including for example NH₃, NH₄OH, CH₃NH₂, C₂H₅NH₂, C₃H₈NH₂, and mixtures thereof. Of these gases, NH₃ is preferred.

KR19980085478 A discloses an etching process to form a contact hole uses a Reactive Ion Etching (RIE) method, in which the conditions are CF₄ 100˜2000 sccm, CHF₃ 100˜2000 sccm, C₂H₂F₂ 100˜2000 sccm, RF (Radio Frequency) Power 200˜3000 W. pressure 100˜2000 mT, and cathode temperature −40˜40° C.

US2007184605 discloses a method of manufacturing a flash memory device. An etch process for controlling the effective field height of isolation layers is performed using a dry etch process on condition that an excessive amount of polymer is generated, thus forming first spacers on sidewalls of a floating gate pattern. The example of mask material was transition metal, preferably Ni. An etching composition of C₂H₂F₂, C₄F₆ or C₄F₈ or C₅F₈, Ar and O₂, is disclosed, N₂ is not mentioned.

US2009114944 discloses processing a substrate for an LED device formation includes etching with a mask, in which an etchant includes a gas from a list including C₂H₂F₂ and an oxygen containing gas. N₂ is not mentioned. The list of gas includes CF₄, CHF₃, C₂H₂F₂, or C₂F₃Cl₃.

US2009155731 discloses a method of mitigating pattern defects, such as critical dimension (CD) bias and line-edge roughness (LER), during a pattern transfer process is described. The method comprises forming one or more layers on a substrate, forming a radiation sensitive mask layer on the one or more layers, and forming a pattern in the radiation sensitive mask layer using a lithographic process. Once the pattern is formed, the edges of the pattern are smoothed by exposing the pattern in the radiation sensitive mask layer to a fluorohydrocarbon-containing plasma. For example, the process gas may include as incipient ingredients CHF₃, CH₂F₂, C₂HF₅, C₂H₂F₂, or C₂H₄F₂, or any combination of two or more thereof. Additionally, the process gas may further include as an incipient ingredient a fluorocarbon gas, or a hydrocarbon gas, or both. Additionally, the process gas may further include as an incipient ingredient an inert gas, such as a noble gas. Furthermore, the process gas may further include as an incipient ingredient O₂, CO, CO₂, NO, NO₂, N₂O, H₂, N₂ or NH₃, or any combination of two or more thereof.

US2011272813 discloses a method of manufacturing a semiconductor device includes: forming a cap insulating film, including Si and C, on a substrate; forming an organic silica film, having a composition ratio of the number of carbon atoms to the number of silicon atoms higher than that of the cap insulating film, on the cap insulating film; and forming two or more concave portions, having different opening diameters, in the organic silica film, by plasma processing in which mixed gas including inert gas, N-containing gas, fluorocarbon gas and oxidant gas is used. Describes a mixed gas including inert gas, N-containing gas, fluorocarbon gas and oxidant gas is used. The fluorocarbon gas includes gases such as C₂H₂F₂ and CHF₃. N-containing gas includes at least one selected from a group consisting of nitrogen gas, ammonia gas, and amine gas. The purpose is to etch a low k type silicon containing film. The oxidizer gas can be O₂, CO₂, CH₃OH, C₂H₅OH, C₃H₇OH, N₂O, NO, N₂O₃, NO₂, N₂O₄ and N₂O₅. The hard mask material was SiO₂. The cap insulating film is a film made of any of silicon carbide (SiC) and silicon nitride carbide (SiCN), or a laminated film thereof. In addition, the cap insulating film is a film made of oxygen-containing silicon carbide (SiCON) including unsaturated hydrocarbon, amorphous carbon and oxygen, or a laminated film of SiCN, SiC and the oxygen-containing silicon carbide film.

US2009111275 discloses a plasma etching method that can prevent residues from becoming attached to bottoms and sides of via holes and trenches. An interlayer insulation film formed of C_{w}Fₓ (x and w are predetermined natural numbers) and a metallic layer or a metal-containing layer formed on a substrate are exposed at the same time to plasma generated from a process gas. The process gas is a mixed gas including C_{y}F_{z} (y and z are predetermined natural numbers) gas and N₂ gas, and the flow rate of the N₂ gas in the process gas is higher than the flow rate of the C_{y}F_{z} gas. The process gas is C_{y}F_{z} (non-hydrogen containing gas) but in some instance H containing gas is mentioned. For example CF₄ is used as fluorocarbon-based gas (C_{y}F_{z} (y and z are predetermined natural numbers) gas) contained in a process gas, fluorocarbon-based gas contained in a process gas is not limited to this, but may be C₄F₈, C₂F₆, C₃F₈, C₄F₆, or C₅C₈. The same effects as that of the present invention can be expected to be obtained if CHF₃ as hydrogen-containing gas or NF₃ or SF₆ as non-carbon containing gas is used.

US2005186801 discloses a process for the manufacture of a semiconductor integrated circuit device having an inlaid interconnect structure by embedding a conductor film in a recess, such as a trench or hole, formed in an organic insulating film which constitutes an interlevel dielectric film and includes an organosiloxane as a main component, the recess, such as a trench or hole, is formed by subjecting the organic insulating film to plasma dry etching in a CF-based gas/N₂/Ar gas in order to suppress the formation of an abnormal shape on the bottom of the recess, upon formation of a photoresist film over the organic insulating film, followed by formation of the recess therein with the photoresist film as an etching mask. Not only C₄F₈, but also a gas such as CHF₃, CF₄, CH₂F₂ or C₅F₈ can be employed. In addition, a saturated cyclic fluorocarbon, such as C₃F₆, a non-saturated cyclic fluorocarbon, such as C₅F₉, a non-cyclic fluorocarbon, such as CF₄, CHF₃ or CH₂F₂, or fluorocarbon iodide, such as CF₃I developed as a countermeasure against fleon, can be used as a CF gas. Instead of a CF gas, SF₆ can be employed, for example. The dielectric can be an organic spin on glass material. One example given was using a C₄F₈/N₂/Ar etch recipe. In FIG. 9 they show that increasing N₂ flow rate increased the etching rate of the organic SOG and also the etch selectivity towards SiN was increased at a maximum where N₂ flow rate was 200 sccm (Ar flow rate was 420 sccm, so a ratio of ˜0.5) and decreased at higher flow rates of N₂. Also they describe that the usable etching selectivity and etching rate are available at a nitrogen gas flow rate ranging from 150 sccm (C/N ratio: 0.16) to 300 sccm (C/N ratio: 0.08), which may be widened to a range of from 50 sccm (C/N ratio: 0.48) to 500 sccm (C/N ratio: 0.48).

US2014363975 discloses a cyclic etching process, where the deposition gas is chosen from C₄F₈, C₂F₄, C₂H₂F₂ and CCl₄, and there is an etching gas selected from CF₄ and SF₆, the chlorine based etching gas includes Cl₂, BCl₃, SiCl₄, SiCl₂H₂, and the bromine based etching gas includes Br₂ and HBr.

The conventional fluorocarbon and hydrofluorocarbon gases may have a high global warming potential (GWP), and also when exposed to a high power plasma they will break apart and potentially form species that also have high GWPs. These high GWP species are emitted. In some instances these high GWP species may pass through a scrubbing device but these high GWP species have various efficiencies. Thus, there is a need for both lower GWP etching gases that function in etching dielectric materials as well as gases that break down in the plasma and create lower GWP byproducts as compared to the traditional fluorocarbon and hydrofluorocarbon gases used in the semiconductor industry.

Thus, there is a need for both lower GWP etching gases than those of commonly used hydrofluorocarbon and fluorocarbon etching gases, for example CF₄, which function in etching processes and gases that break down in plasma and create lower GWP byproducts than those of the commonly used hydrofluorocarbon and fluorocarbon etching gases.

### SUMMARY

Disclosed is an etching method for forming a structure by selectively etching one or more dielectric films in a substrate using a patterned mask layer deposited on top of the one or more dielectric films, the method comprising:
mounting the substrate in a reaction chamber;
introducing an etching gas containing C₂H₂F₂ into the reaction chamber;
converting the etching gas to a plasma; and
allowing an etching reaction to proceed between the plasma and the one or more dielectric films so that the one or more dielectric films are selectively etched versus the patterned mask layer to form the structure. The disclosed etching method may include one or more of the following features:
further comprising
adding one or more hydrofluorocarbon or fluorocarbon etching gases to C₂H₂F₂, wherein the one or more fluorocarbon etching gases are selected from CF₄, C₂F₆, C₃F₈, C₄F₆, C₄F₈, C₂F₄, C₃F₆, C₄F₁₀, C₅F₈, or C₆F₆, C₇F₁₄, C₇F₁₆, or C₈F₁₆, wherein the one or more hydrofluorocarbon etching gases are C₁-C₈ hydrofluorocarbon CₓF_{y}H_{z} molecules, where x, y and z are integers, 1≤x≤8, selected from CHF₃, CH₂F₂, CH₃F, C₂HF₅, C₂H₅F, C₂H₅F, C₃H₇F, C₃H₂F₆, C₃H₂F₄, C₃H₂F₆, C₃H₄F₂, C₄H₂F₆, C₄H₃F₇, C₅F₁₀, C₅HF₇, or combination thereof;
further comprising adding an additive to C₂H₂F₂, wherein the additive is selected from H₂, SF₆, NF₃, NH₃, Cl₂, BCl₃, BF₃, Br₂, F₂, FNO, FNO₃, HBr, HCl, HI, IF₅, IF₇, or HF;
further comprising adding a co-reactant to C₂H₂F₂;
the co-reactant is an inert gas selected from Ar, Kr, Xe, Ne, N₂, He or combination thereof;
the co-reactant being selected from N₂, Ar or a combination of both with any ratios of each ranging from 0-100%;
the co-reactant being selected from N₂, Ar or a combination being of both;
the combination of N₂ and Ar having a ratio of each ranging from 0-100%;
further comprising
adding a co-reactant N₂ to C₂H₂F₂;
further comprising adding a co-reactant Ar to C₂H₂F₂;
C₂H₂F₂ being an isomer of C₂H₂F₂ with CAS No.: 75-38-7;
C₂H₂F₂ being an isomer of C₂H₂F₂ with CAS No.: 1630-78-0;
C₂H₂F₂ being an isomer of C₂H₂F₂ with CAS No.: 1630-77-9;
C₂H₂F₂ being an isomer of C₂H₂F₂ with CAS No.: 1691-13-0;
the temperature of the substrate ranging from −20 to 300° C.;
the temperature of the substrate ranging from −20 to −196° C.;
the pressure in the chamber being between approximately 0.1 mTorr and approximately 1000 Torr;
the pressure in the chamber being between approximately 1 mTorr and approximately 10 Torr;
the pressure in the chamber being between approximately 10 mTorr and approximately 1 Torr;
the pressure in the chamber ranging from single mTorr to hundreds of mTorr;
the pressure in the chamber being maintained between 15 and 30 mTorr;
the one or more dielectric films being SiO₂ and SiOCH films;
CO₂ equivalent emissions from the reaction chamber being at least 10% lower than that of using CF₄ as an etching gas; and
CO₂ equivalent emissions from the reaction chamber being equal to or greater than 10% lower than that of using CF₄ as an etching gas.

Disclosed is an etching method for forming a structure with lower CO₂ equivalent emission by selectively etching one or more dielectric films in a substrate using a patterned mask layer deposited on top of the one or more dielectric films, the method comprising:
mounting the substrate in a reaction chamber;
introducing an etching gas containing C₂H₂F₂ into the reaction chamber;
converting the etching gas to a plasma; and
allowing an etching reaction to proceed between the plasma and the one or more dielectric films so that the one or more dielectric films are selectively etched versus the patterned mask layer to form the structure,
   wherein CO₂ equivalent emissions from the reaction chamber is at least 10% lower than that of using CF₄ as an etching gas. The disclosed etching method may include one or more of the following features:
further comprising
adding one or more hydrofluorocarbon or fluorocarbon etching gases to the etching gas C₂H₂F₂, wherein the one or more fluorocarbon etching gases are selected from CF₄, C₂F₆, C₃F₈, C₄F₆, C₄F₈, C₂F₄, C₃F₆, C₄F₁₀, C₅F₈, C₆F₆, C₇F₁₄, C₇F₁₆, or C₈F₁₆, wherein the one or more hydrofluorocarbon etching gases are C₁-C₈ hydrofluorocarbon CₓF_{y}H_{z} molecules, where x, y and z are integers, 1≤x≤8, selected from CHF₃, CH₂F₂, CH₃F, C₂HF₅, C₂H₅F, C₂H₅F, C₃H₇F, C₃H₂F₆, C₃H₂F₄, C₃H₂F₆, C₃H₄F₂, C₄H₂F₆, C₄H₃F₇, C₅F₁₀, C₅HF₇, or combination thereof;
further comprising adding an additive to C₂H₂F₂, wherein the additive is selected from H₂, SF₆, NF₃, NH₃, Cl₂, BCl₃, BF₃, Br₂, F₂, FNO, FNO₃, HBr, HCl, HI, IF₅, IF₇, or HF;
further comprising adding a co-reactant to C₂H₂F₂;
the co-reactant being an inert gas selected from Ar, Kr, Xe, Ne, N₂, He or combination thereof;
the co-reactant being selected from N₂, Ar or a combination of both with any ratios of each ranging from 0-100%;
the co-reactant being selected from N₂, Ar or a combination being of both;
the combination of N₂ and Ar having a ratio of each ranging from 0-100%;
further comprising adding a co-reactant N₂ to C₂H₂F₂;
further comprising adding a co-reactant Ar to C₂H₂F₂;
C₂H₂F₂ being an isomer of C₂H₂F₂ with CAS No.: 75-38-7;
C₂H₂F₂ being an isomer of C₂H₂F₂ with CAS No.: 1630-78-0;
C₂H₂F₂ being an isomer of C₂H₂F₂ with CAS No.: 1630-77-9;
C₂H₂F₂ being an isomer of C₂H₂F₂ with CAS No.: 1691-13-0; and
the temperature of the substrate ranging from −20 to 300° C.

Disclosed is an etching method for forming a structure by selectively etching one or more dielectric films in a substrate using a patterned mask layer deposited on top of the one or more dielectric films, the method comprising:
mounting the substrate in a reaction chamber;
introducing an etching composition including a gas mixture of C₂H₂F₂ and an inert gas into the reaction chamber;
converting the etching composition to a plasma; and
allowing an etching reaction to proceed between the plasma and the one or more dielectric films so that the one or more dielectric films are selectively etched versus the patterned mask layer to form the structure,
wherein the temperature of the substrate ranges from −20 to 300° C. The disclosed etching method may include one or more of the following features:
the inert gas being selected from Ar, Kr, Xe, Ne, N₂, He or combinations thereof;
the inert gas being selected from N₂, Ar or a combination of both of any ratio each ranging from 0-100%;
the inert gas being selected from N₂, Ar or a combination being of both;
the combination of N₂ and Ar having a ratio of each ranging from 0-100%;
the inert gas being N₂;
the inert gas being Ar; and
C₂H₂F₂ being an isomer of C₂H₂F₂ with CAS No.: 75-38-7.

### Notation and Nomenclature

The following detailed description and claims utilize a number of abbreviations, symbols, and terms, which are generally well known in the art, and include:

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from previous manufacturing steps. For example, the wafers may include silicon layers (including, but not limited to, crystalline, amorphous, porous, etc.), silicon containing layers (including, but not limited to, SiO₂, SiN, SiON, SiCOH, etc.), metal or metal containing layers (including, but not limited to, copper, cobalt, ruthenium, tungsten, platinum, palladium, nickel, ruthenium, gold, etc.) or combinations thereof. Furthermore, the substrate may be planar or patterned. The substrate may be an organic patterned Iodinated carbon layer film. The substrate may include layers of oxides that are used as dielectric materials in field effect transistor (FET) such as FinFET, MOFSET, GAAFET(Gate all-around FET), Ribbon-FET, Nanosheet, Forksheet FET, Complementary FET (CFET), MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. The substrate may include layers of alternating oxides (e.g., SiO) and nitrides (e.g., SiN). One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates. The substrate may be any solid that has functional groups on its surface that are prone to react with the reactive head of a self-assembled monolayer (SAM), and may include without limitation 3D objects or powders.

The term “wafer” or “patterned wafer” refers to a wafer that has a stack of films on a substrate, at least the top-most film the stack of the films has topographic features or patterns that have been created in steps prior to etch and the patterned top-most film on is formed for pattern etch.

The term “processing” as used herein includes patterning, exposure, development, etching, deposition, cleaning, and/or removal of by-products, as required in forming a described structure.

The term of “deposit” or “deposition” refers to a series of processes where materials at atomic or molecular levels are deposited on a wafer surface or on a substrate from a gas state (vapor) to a solid state as a thin layer. Chemical reactions are involved in the process, which occur after creation of a plasma of the reacting gases or activation of the reacting gases by heat. The plasma may be capacitively coupled plasma (CCP), Inductively coupled plasma (ICP), electron cyclotron resonance (ECR) plasma, or a microwave plasma, but is not limited to. Suitable commercially available plasma etching chambers include but are not limited to the Lam Research Dual CCP reactive ion etcher Dielectric etch product family sold under the trademark Flex™ or the Tokyo Electron Tactras™ or Episode™ UL. The non-plasma exposure step may be performed in a different chamber than the plasma exposure step.

The term “aspect ratio” refers to a ratio of the height of a trench (or aperture) to the width of the trench (or the diameter of the aperture).

Note that herein, the terms “film”, “layer” and “material” may be used interchangeably. It is understood that a film may correspond to, or related to a layer or a material, and that the layer may refer to the film and the material. Furthermore, one of ordinary skill in the art will recognize that the terms “film” or “layer” or “material” used herein refer to a thickness of some material laid on or spread over a surface and that the surface may range from as large as the entire wafer to as small as a trench or a line.

Note that herein, the terms “aperture”, “via”, “hole”, “trench” and “structure” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “etch gas” and “etchant” may be used interchangeably when the etch gas is in a gaseous state at room temperature and ambient pressure. It is understood that an etch gas may correspond to, or be related to an etchant, and that the etchant may refer to the etch gas.

The terms “dope” or “doping” is used interchangeably to the process of incorporation of one or more elements into a film through various methods where that element may be chemically bond or physically bond, and the process of intentionally incorporating atoms of different elements into the film composition. The element(s) may be doped interstitial or substitutional within the film.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “hydrofluorocarbon” refers to a saturated or unsaturated function group containing exclusively carbon, fluoride and hydrogen atoms.

As used herein, the term “fluorocarbon” refers to a saturated or unsaturated function group containing exclusively fluoride and hydrogen atoms.

As used herein, the term “GWP” refers to the Global Warming Potentials, typically on a 100 year timescale and comparing the global warming potential to CO₂.

As used herein, “CO₂ emission” or “CO₂ equivalent emission” refers to a comparison between C₂H₂F₂ and gases like CF₄ and CHF₃, commonly used fluorocarbon and hydrofluorocarbon etching gas and the GWP of the emitted species from a plasma etch process.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term that means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a FTIR spectrum of emissions from a CHF₃ plasma etch process of etching SiO₂ film;

FIG. 2 is a FTIR spectrum of emissions from a C₂H₂F₂ plasma etch process of etching SiO₂ film;

FIG. 3 is etch rates of two etching gases, C₂H₂F₂ and CHF₃, in etching processes of etching SiO₂ film with high and low plasma source powers;

FIG. 4 is SiO₂ etch rate as a function of N₂ or O₂ addition for C₂H₂F₂/Ar etch;

FIG. 5 is Low-k dielectric etch rate as a function of N₂ or O₂ addition for C₂H₂F₂/Ar etch;

FIG. 6 is a comparison of etch rates for CF₄, CHF₃, CF₃I, and C₂H₂F₂ to polySi, SiO₂, SiN and SOC films;

FIG. 7 is a comparison of selectivities for CF₄, CHF₃, CF₃I, and C₂H₂F₂ to polySi, SiO₂, SiN and SOC films;

FIG. 8 is mass spectra of pure CHF₃;

FIG. 9 is mass spectra of pure C₂H₂F₂; and

FIG. 10 is mass spectra of pure CF₄.

### DESCRIPTION OF PREFERRED EMBODIMENTS

Disclosed are methods of plasma etching dielectric materials or layers and/or Si-containing materials or layers to form patterned structures using a hydrofluorocarbon etching gas C₂H₂F₂ to manufacture semiconductor chips, such as back-end-of-line (BEOL) or interconnects (trench and via etch) for logic devices, and high-k etch, such as transistor and gate patterning), slit etch, patterning etches, recess etch, or mask breakthrough. The dielectric materials or layers may be silicon containing layers such as SiO₂, and low-k (such as SiOCH films) materials or layers.

The conventional fluorocarbon and hydrofluorocarbon gases may have a high global warming potential (GWP), and also when exposed to a plasma they break apart and potentially form species that also have high GWPs. These high GWP species are emitted. In some instances, even where the byproducts are scrubbed, the scrubbing process may be incomplete as not 100% of fluorinated species are converted to CO₂; moreover, plasma and thermal scrubbers may even create high GWP byproducts from these reactions.

The disclosed plasma etching method using C₂H₂F₂ with an inert co-reactant, such as N₂, achieves CO₂ equivalent emission from the reaction chamber at least 10% reduction comparing to commonly used hydrofluorocarbon etching gas. For example, comparing to CF₄, the disclosed plasma etching method provides at least 10% reduction of CO₂ equivalent emission from the reaction chamber comparing to CO₂ equivalent emission by using CF₄ as an etching gas. That is, CO₂ equivalent emissions from the reaction chamber using C₂H₂F₂ is at least 10% lower than that of using CF₄ as an etching gas.

As shown in Table 1, C₂H₂F₂ is particularly attractive due to its very low GWP of <1 whereas other traditional fluorocarbon and hydrofluorocarbon etching gases have very high GWP, such as CH₂F₂ having a GWP of 677.

C₂H₂F₂ has 4 primary isomers listed below in Table 2. Here the preferable C₂H₂F₂ molecule is CAS No.: 75-38-7.

TABLE 2

| | | | | Boiling |
|---|---|---|---|---|
| Name | Formula | Structure | CAS No. | Point |
| 1,1-difluoroethylene | C₂H₂F₂ | 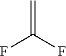 | 75-38-7 | −83º C. |
| (E)-1,2-difluoroethylene | C₂H₂F₂ | 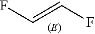 | 1630-78-0 | −86° C. |
| (Z)-1,2-difluoroethylene | C₂H₂F₂ | 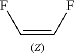 | 1630-77-9 | −36° C. |
| 1,2-difluoroethene | C₂H₂F₂ | 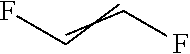 | 1691-13-0 | −28° C. |

C₂H₂F₂ is supplied in a gas cylinder at a variety of fill quantities, pressure and specifications. Preferably C₂H₂F₂ in the cylinder has a low moisture content of <40 ppm, preferably <10 ppm. C₂H₂F₂ may be purified to remove critical impurities such as other fluorocarbons, hydrofluorocarbons, chlorofluorocarbons (CFC's), impurities from air such as N₂, O₂, CO₂, moisture (H₂O), HF and other hydrocarbons such as CH₄, etc., using distillation, adsorption by molecular sieves, or other existing methods. Some impurities may form azeotropes, thus, other purification methods may need to be employed using chemical methods to separate them.

The disclosed plasma etching method comprises exposing a substrate to an etching gas C₂H₂F₂ and/or one of its isomers, preferably C₂H₂F₂ CAS No.: 75-38-7, in a reaction chamber during a plasma etching process and/or during a chamber conditioning process.

The disclosed plasma etching method for forming an aperture or a structure by selectively etching one or more dielectric films in a substrate using a patterned mask layer deposited on top of the one or more dielectric films, the method comprising:
mounting the substrate in a reaction chamber;
introducing an etching gas containing C₂H₂F₂ into the reaction chamber;
converting the etching gas to a plasma; and
allowing an etching reaction to proceed between the plasma and the one or more dielectric films so that the one or more dielectric films are selectively etched versus the patterned mask layer to form the structure.

The reaction chamber may be any enclosure or chamber within a device in which etching methods take place, such as, without limitation, a reactive ion etching (RIE), a CCP with single or multiple frequency RF sources, an inductively coupled plasma (ICP), a microwave plasma reactors, or other types of etching systems capable of plasma processing, that is, selectively removing a portion of a dielectric film or generating active species or depositing films.

The reaction chamber is equipped with parallel plate electrodes plasma generators where a high frequency electromagnetic field of 60 MHz is applied to the upper electrode and a 2 MHz one is applied to the lower electrode, when the gap between the electrodes is kept in a range between 10 and 35 mm. Combination of these electric fields allows applying power to the upper electrode within a range of 0-2000 W and to the lower electrode within the range of 1500-7000 W. The plasma may be generated with a total RF power ranging from about 25W to about 100 kW. The plasma may be generated remotely or within the reaction chamber itself. RF frequency of the plasma may range from 100 KHz to 1 GHz. The plasma may be pulsed or continuous wave. In some embodiments, the power applied to the chamber may range from 0 to several kW of bias power and hundreds to several thousand kW of source power.

Temperature and pressure within the reaction chamber are held at conditions suitable for the processing films to react with the activated etching gas C₂H₂F₂. For instance, the pressure in the chamber may be held between approximately 0.1 m Torr and approximately 1000 Torr, preferably between approximately 1 mTorr and approximately 10 Torr, more preferably between approximately 10 m Torr and approximately 1 Torr, as required by etching parameters. In some embodiments, the pressure in the chamber may range from single mTorr to hundreds of mTorr. Pressure in the etching chamber during the plasma-etching process is maintained between 15 and 30 mTorr with introduced an etching gas mixture. Likewise, substrate temperature in the reaction chamber or temperature of the reaction chamber may range from −20 to 300° C. though lower temperatures ranging from −20 to −196° C. are possible. Reaction chamber wall temperature may be around >−20° C., preferably <300° C. The reaction chamber wall temperature may be around room temperature or larger than room temperature but less than 300° C. depending on process requirements. In some embodiments, the substrate temperature in the reaction chamber may range from 20 to 200° C.

Additional one or more hydrofluorocarbon or fluorocarbon etching gases may be added to C₂H₂F₂. The additional one or more fluorocarbon etching gases may be selected from CF₄, C₂F₆, C₃F₈, C₄F₆, C₄F₈, C₂F₄, C₃F₆, C₄F₁₀, C₅F₈, or C₆F₆, C₇F₁₄, C₇F₁₆, or C₈F₁₆. The additional one or more hydrofluorocarbon etching gases may be selected from C₁-C₆ hydrofluorocarbon CₓF_{y}H_{z} molecule (x, y and z are integers, 1≤x≤8,) selected from CHF₃, CH₂F₂, CH₃F, C₂HF₅, C₂H₅F, C₂H₅F, C₃H₇F, C₃H₂F₆, C₃H₂F₄, C₃H₂F₆, C₃H₄F₂, C₄H₂F₆, C₄H₃F₇, C₅F₁₀, C₅HF₇, or combination thereof.

Referring to Table 1, some hydrofluorocarbons or fluorocarbons have high GWP comparing to that of C₂H₂F₂. In order to enhance the etching performance and etching quality, one or more hydrofluorocarbon or fluorocarbon etching gases may be added to C₂H₂F₂ to slightly tune the etching performance. When a little amount of hydrofluorocarbons or fluorocarbons with high GWP values is added, the overall CO₂ equivalent emission from the reaction chamber may not impact a lot considering the improved etching performance. For example, less than 10% of one or more hydrofluorocarbon or fluorocarbon etching gases versus C₂H₂F₂ is added to C₂H₂F₂, the CO₂ equivalent emission from the reaction chamber may not change significantly comparing to the significantly improved etching performance. In reality, reducing the CO₂ equivalent emissions and high etching performance may need to be balanced.

Other gases, such as additives, may be added to C₂H₂F₂. The additives include H₂, SF₆, NF₃, NH₃, Cl₂, BCl₃, BF₃, Br₂, F₂, FNO, FNO₃, HBr, HCl, HI, IF₅, IF₇, or HF.

A co-reactant, such as an inert gas, may also be added to the etching gas C₂H₂F₂. The inert gas is selected from He, Ar, Kr, Xe, Ne, N₂, or combination thereof. In some embodiments, N₂, Ar or a combination of both may be added to C₂H₂F₂. The combination of N₂ and Ar may have any ratios of each ranging from 0-100%. The flow rates of C₂H₂F₂, N₂, and Ar may range from 1 sccm to 10 slm, preferably larger than 10 sccm and less than 1 slm. Different flow rate ratios of C₂H₂F₂/N₂/Ar may be applied. Here, N₂ and/or Ar may be replaced with other inert gases, such as Kr, Xe, Ne, He or combination thereof. In some embodiments, N₂ may be added to C₂H₂F₂. In some embodiments, Ar may be added to C₂H₂F₂.

The etch process may be continuous or cyclic. For cyclic etch like atomic layer etching process, where the etchant is Ar in the plasma etching step and C₂H₂F₂ is a precursor in the deposition step. During the deposition step the source plasma power is on, the bias is off. For the etching step the source and bias powers both are on, producing a mixture of gaseous byproducts exiting the plasma etch chamber that has a lower GWP as compared to a process using traditional fluorocarbon etching gases such as CF₄ or CHF₃.

The C₂H₂F₂ etch step may be carried out independently on an already exposed dielectric substrate, or may be one step within a longer overall etch recipe including mask opening steps, lower layer breakthrough etch steps, or post etch cleaning steps. Various advanced process control mechanisms may be employed for the C₂H₂F₂ etch process, including but not limited to, wafer order based etch time or flow rate corrections to account for cross lot effects, preventative maintenance (PM) cycle based time or flow rate corrections to account for cross PM effects, pre lot or mid lot chamber seasoning to account for cross lot effects, post wafer lot chamber cleaning to reset chamber condition, OES based endpointing for landed etches, feed forward or feedback based time or flow rate corrections to control depth or CDs of etched features.

The substrate contains dielectric materials or films, such as SiO₂, SiOCH. One example is a dielectric film layer as used in interconnect metal layers. The dielectric film comprised a layer of SiO or SiOCH. The dielectric film or material comprises one or more layers of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON.

Materials to be etched include silicon-containing film such as SiO₂, carbon-containing-SiO₂ such as low-k dielectrics SiOCH, formed by PECVD, spin on deposition, or other methods, crystalline and polySi, SiN, metals and their oxides (Ti, Pt, W, Al), mask materials including organic based materials such as photoresist, spin-on-carbon, amorphous carbon, nitrides such as SiN and TiN and metals and their oxides (Ti, Pt, W, Al). Preferably the material to be etched is SiO₂ or SiOCH low-k dielectric materials.

Here, the SiO films may include but not limited to Si, O, C, B, N, H containing films deposited using CVD (with or without plasma), spin on deposition or other methods. The silicon-containing film could also be a silicon oxide based dielectric material such as organic based or silicon oxide based low-k dielectric materials such as the Black Diamond I, II or III material by Applied Materials, Inc. with a formula of SiOCH. The silicon-containing film may also include SiₐO_{b}N_{c} where a, b, c range from 0.1 to 6. The silicon-containing films may also include dopants, such as B, C, P, As and/or Ge. The film may be porous with a wide range of pore size.

On top of the dielectric films or materials is a mask layer or mask material. The mask material may be a layer of amorphous carbon, doped amorphous carbon, SOC (spin on carbon), Si, SiN, Al, AlO, Ti, TiO, other metal and metal oxide masks, or other nitrides such as TiN, with or without dopants.

C₂H₂F₂ is supplied in a gas cylinder at a variety of fill quantities, pressure and specifications. Preferably the material has a low moisture content of <40 ppm, preferably <10 ppm. C₂H₂F₂ may be purified to remove critical impurities such as chlorine-species or organochlorides, other fluorocarbons, hydrofluorocarbons, chlorofluorocarbons (CFC's), impurities from the air (N₂, O₂, CO₂), moisture (H₂O), HF other hydrocarbons (CH₄, etc.), using distillation, adsorption using molecular sieves, or other commonly known methods in the art. Some impurities may form azeotropes thus other purification methods may need to be employed using chemical means to separate them. The primary application of the disclosed plasma etching method is use of C₂H₂F₂ and N₂ or C₂H₂F₂, N₂ and Ar for plasma etching of silicon containing layers such as SiO₂ or SiOCH selectively with a mask such as nitrides like SiN or TiN or carbon (amorphous or SOC for example) to manufacture a semiconductor device and reduce the CO₂eq (CO₂ equivalent) GWP emissions of the etching process. Not only does C₂H₂F₂ have a much lower GWP than standard or commonly used fluorochemical etching gases, it also produces lower GWP emissions from etching processes than those of using the standard fluorochemical etching gases such as CF₄ as an etching gas. Such etching processes are often used in back end of line dielectric etching processes to form trenches, vias, spacers to manufacture logic devices. C₂H₂F₂ and N₂ or C₂H₂F₂, N₂ and Ar may also be used to manufacture memory devices and a wide variety of other semiconductor devices.

The disclosed plasma etch method using C₂H₂F₂ as etching gas to etch dielectric films producing apertures, such as channel holes, gate trenches, staircase contacts, capacitor holes, contact holes, contact etch, slit etch, self-aligned contact, self-aligned vias, super vias etc., in silicon-containing films. Dimensional of etched structures may range from nm to cm patterned features with nm to mm vertical depths. Applications may range from pattern transfer (e.g., trilayer etch, pitch multiplication, etch stop breakthrough), dielectric etch (trench, via, contact) to small feature (gate, source, drain patterning) to large feature (through silicon via, memory channel). Structures can be but not limited to trench, holes, plugs, etc.

The disclosed plasma etching method is not limited to the above stated experimental conditions in any way, types of plasma etching tool (e.g., capacity coupled or inductively coupled plasma), process conditions (e.g., pressure, power, temperature, duration of process), process gas mixture, combination and proportion of gases in the process gas mixture, gas flow, workpiece and plasma etching chamber itself may be altered for each process and during the process.

In summary, the disclosed plasma etching methods provide using C₂H₂F₂ to enhance control of the deposition profile of the polymer film, as well as to etch dielectric materials with high etch rates and selectivity. Additionally, C₂H₂F₂ has a lower GWP compared to commonly used ones (e.g., CF₄, CHF₃, C₄F₈, CH₂F₂), enabling more eco-friendly processes, e.g., CO₂ equivalent emissions from the reaction chamber using C₂H₂F₂ is at least 10% lower than that of using CF₄ as an etching gas.

### EXAMPLES

A more detailed description of the disclosed methods through examples is provided as follows. However, the disclosed methods is not limited to presented examples in any way and process conditions, process gas mixture, combination and proportion of gases in the gas mixture, workpiece and plasma etching chamber itself may be altered.

In the following Examples, the primary plasma etching source may be a CCP plasma but may also include other sources such as ICP, microwave, ECR, etc. The plasma may be used in a continuous source or as a pulsed plasma of a certain frequency and duty cycle. Additional fluorocarbon gases may be added to slightly tune the etching performance. Additional inert gases may be added such as Kr, Xe, Ne, Ne as well as hydrogen source gases such as H₂, and hydrocarbons. The mask material may include TiN or other metal nitride materials, SiN, Si, carbon materials, or the like.

### Example 1 FTIR of Emissions from CHF₃ Plasma Etch Process

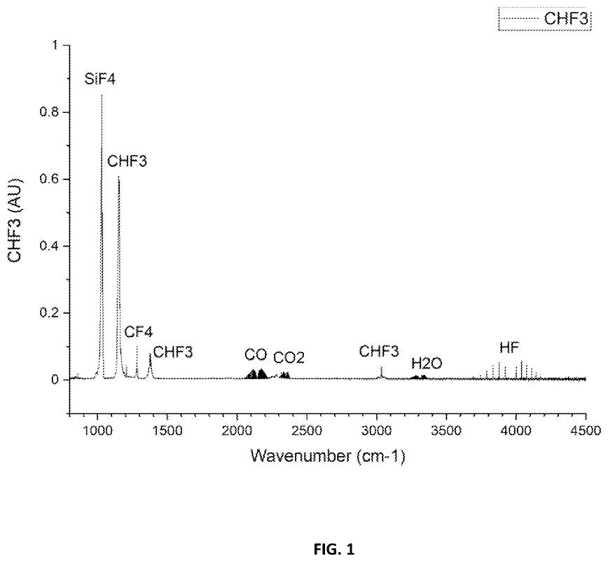

A FTIR of emissions from a CHF₃ plasma etch process of etching SiO₂ film was measured and the FTIR spectrum is shown in FIG. 1. Process conditions are as follows. Temperature was 20/150° C. ESC/UEL (electrostatic chuck or wafer temperature/upper electrode); plasma source power was 500 W source plus 150 W bias; pressure was 20 mTorr; and flow rates of CHF₃/N₂ were 20/80 sccm for 60 s. As shown, the primary emitted species are SiF₄, CHF₃, CF₄, CO, CO₂, and HF.

### Example 2 FTIR of Emissions from C₂H₂F₂ Plasma Etch Process

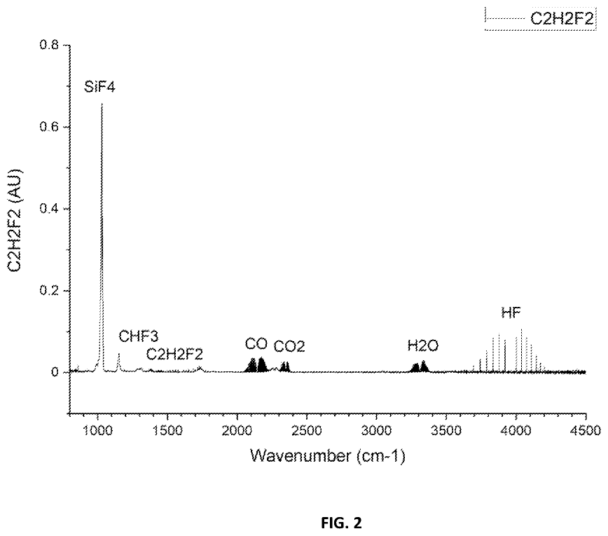

A FTIR of emissions from a C₂H₂F₂ plasma etch process of etching SiO₂ film was measured and the FTIR spectrum is shown in FIG. 2. Process conditions are as follows. Temperature was 20/150° C. ESC/UEL (electrostatic chuck or wafer temperature/upper electrode); plasma source power was 500 W source plus 150 W bias; pressure was 20 mTorr; and flow rates of C₂H₂F₂/N₂ were 20/80 sccm for 60 s. As shown, the primary emitted species are SiF₄, CHF₃, CF₄, CO, CO₂, and HF. As can be seen when comparing FIG. 1 to FIG. 2, the CHF₃ and CF₄ peaks are much smaller for C₂H₂F₂ spectrum as compared to CHF₃ indicating the emitted species for C₂H₂F₂ have much lower GWP.

### Example 3 C₂H₂F₂ and CHF₃ Plasma Etching Processes

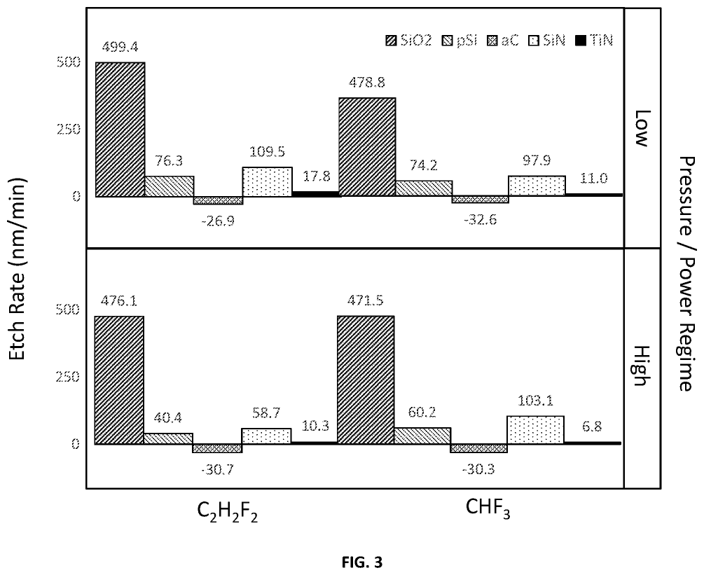

Two different source powers of 2000 W and 500 W were used with 100 W bias power in a 300 mm dielectric CCP etch tool at a pressure of 25 mTorr and 5 mTorr. Two etching gases, C₂H₂F₂ and CHF₃, were evaluated in etching processes of etching SiO₂ film. The results are shown in FIG. 3. Etching composition includes C₂H₂F₂, Ar and N₂, or CHF₃, Ar and N₂, respectively. The flow rate of C₂H₂F₂ or CHF₃ was 15 sccm. The flow rates of Ar and N₂ each were 52.5 sccm. Wafer temperature was 20° C. The high pressure was 25 mTorr and the low pressure was 5 mTorr. As shown, C₂H₂F₂ has higher selectivity of etching SiO₂ vs TiN mask material by using N₂ and Ar as compared to that of CHF₃ by using N₂ and Ar. No O₂ was used in the etching processes. Traditionally O₂ is used as a co-reactant in the plasma etching process to control the polymerization. However, based on the results in FIG. 3, it is found that N₂ is effective to control the polymerization with C₂H₂F₂. For each etching composition good selectivity to mask materials (like TiN) were achieved, thus, the polymerization was controlled by the addition of N₂ and Ar without O₂. The selectivity of etching SiO₂ vs TiN at the low power source of 500 W for CHF₃ is 46 and for C₂H₂F₂ is 70. As such, a much higher selectivity using C₂H₂F₂ rather than CHF₃ is observed with an increase in selectivity of 52%. At the high source power of 2000 W, the selectivity of etching SiO₂ vs TiN for CHF₃ was 28 and for C₂H₂F₂ was 44, an increase in selectivity of 57%, as shown in Table 3. As shown, C₂H₂F₂/N₂/Ar maintains a higher selectivity than the equivalent composition using CHF₃ at both low and high source powers.

TABLE 3

| | SiO₂:TiN selectivity @ | SiO₂:TiN selectivity @ |
|---|---|---|
| Chemistry | low power | high power |
| CHF₃/N₂/Ar | 46 | 28 |
| C₂H₂F₂/N₂/Ar | 70 | 44 |

### Example 4: C₂H₂F₂ Etch with N₂ or O₂

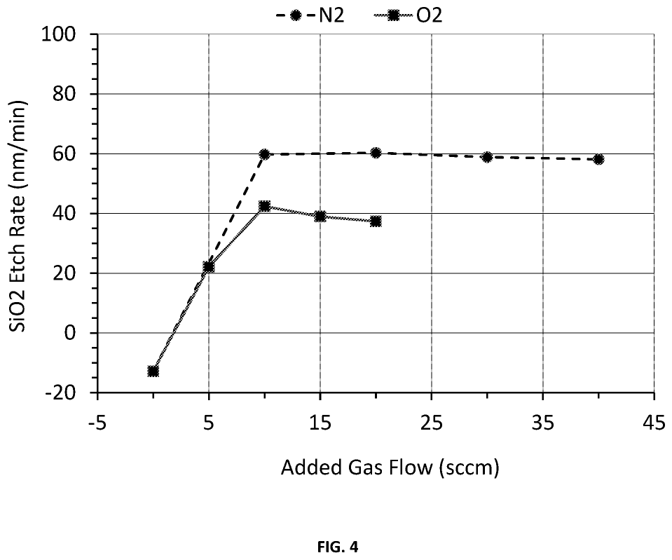

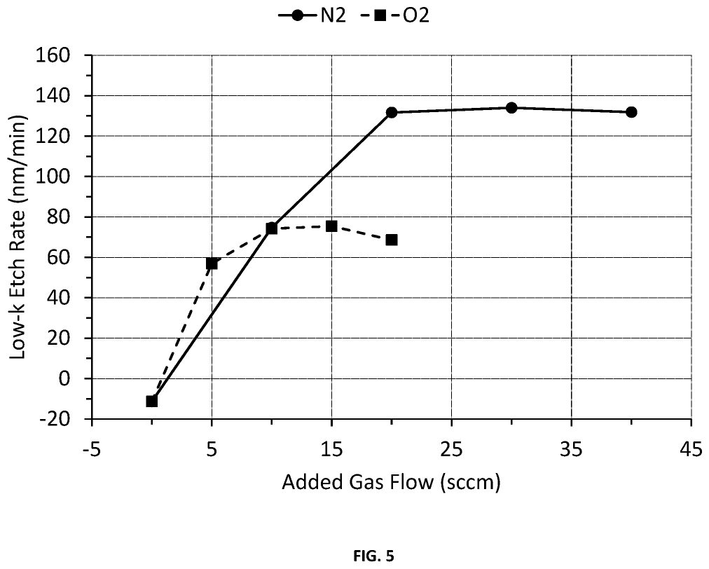

At different plasma and flow conditions, SiO₂ etching rate was evaluated using C₂H₂F₂ as a function of O₂ and N₂. The conditions were as follows. The plasma RF source power was varied from 400 W to 800 W and the bias power was 150 W. The pressure was 10 mTorr and the flow rates of C₂H₂F₂ was 15 sccm. The flow rates of O₂, Ar and N₂ were adjusted. The wafer temperature was 20° C. At a flow rate of 15 sccm of C₂H₂F₂ it took 10 sccm of O₂ to reach an etch rate of ˜35 nm/min. However, without O₂ and the addition of 40 sccm of N₂ the etching rate of SiO₂ was ˜55 nm/min. Therefore, the etching rate of SiO₂ was significantly higher with C₂H₂F₂ by adding N₂ instead of O₂, as shown in FIG. 4. FIG. 5 is low-k etching rate as a function of flow rate of O₂. The etching rate for the addition of O₂ is similar to N₂ up to a flow rate of 10 sccm however at higher flow rates the etching rate with added O₂ is faster than with N₂.

### Example 5: C₂H₂F₂ Etch Comparing to CF₄, CHF₃ and CF₃I

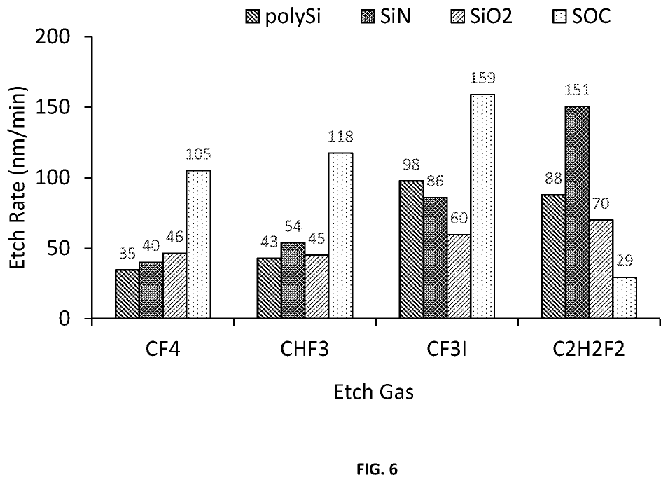

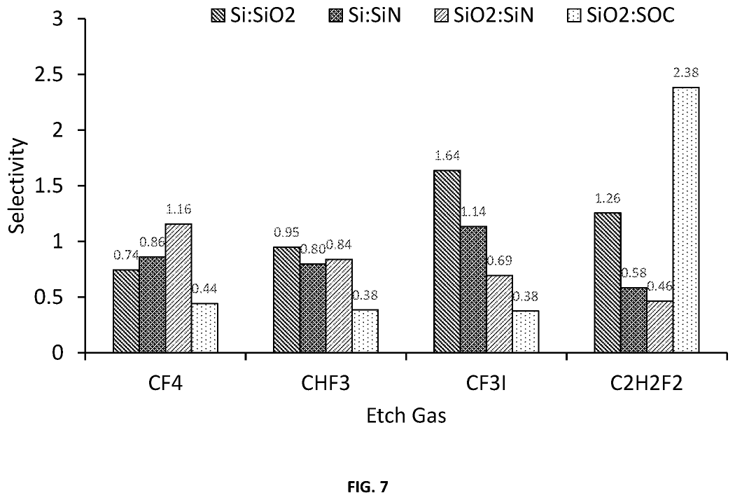

The etch rates and selectivities for 4 different fluorocarbon etching gases, C₂H₂F₂, CF₄, CHF₃ and CF₃I, were measured under similar etching conditions in a 300 mm CCP plasma etch tool. This comparison includes 2 very higher GWP gases (CF₄ and CHF₃) and two lower GWP gases (CF₃I and C₂H₂F₂). The results are shown in FIG. 6 and FIG. 7. Process conditions are as follows. Temperature was 20/150° C. ESC/UEL; plasma source power was 500 W source+150 W bias; pressure was 20 mTorr; flow rate of the etching gases were 20 sccm for 60 s; flow rate of N₂ was 80 sccm N₂ for 60 s. Under these conditions, C₂H₂F₂ had the highest etch rate of SiO₂ as well as the highest selectivity of etching SiO₂ vs SOC (spin on carbon mask material). Therefore the lower GWP gas C₂H₂F₂ provides improved etching performance as compared to both lower GWP and higher GWP gases.

### Example 6: Emissions of CF₄, CHF₃, and C₂H₂F₂ Etching Process

The emissions of CF₄, CHF₃, and C₂H₂F₂ etching processes of etching SiO₂ film were measured on a 300 mm plasma etch tool. The experimental conditions were the same for each gas as temperature was 20/150° C. ESC/UEL; plasma source power was 500 W source+150 W bias; pressure was 20 mTorr, and flow rates were 20 sccm for the etching gas and 80 sccm for N₂ for 60 s. The emissions of an equivalent etching rate process between C₂H₂F₂, CF₄, CHF₃ were quantified. It was found that the CHF₃ process had a CO₂eq (CO₂ equivalent) emissions of 1.87E−04 g/wafer, CF₄ process had a CO₂eq emissions of 4.61E−04 and the C₂H₂F₂ process was 3.88E−05 g/wafer. The CO₂eq emissions for the C₂H₂F₂ was only 20% of the emissions of the equivalent CHF₃ process (80% reduction) and 8% of CF₄ (92% reduction). As such not only may C₂H₂F₂ give improved selectivity of etching SiO₂ VS TiN and SOC but also drastically reduce the CO₂eq emissions. This demonstrates that C₂H₂F₂ has both a lower GWP and lower GWP emissions as compared to CHF₃ and/or CF₄.

### Example 7: Mass Spectrum of CF₄, CHF₃ and C₂H₂F₂ Etching

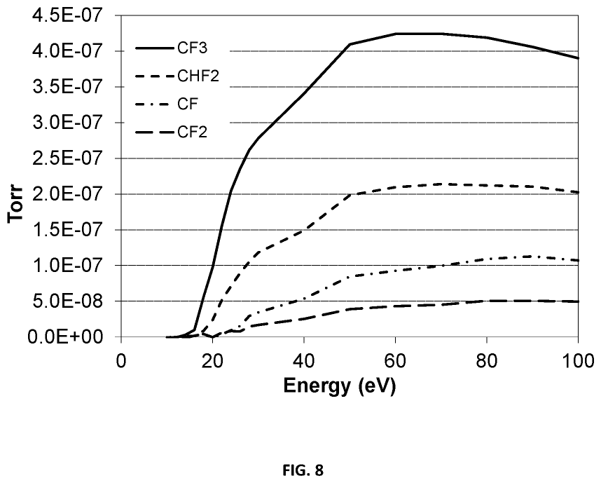

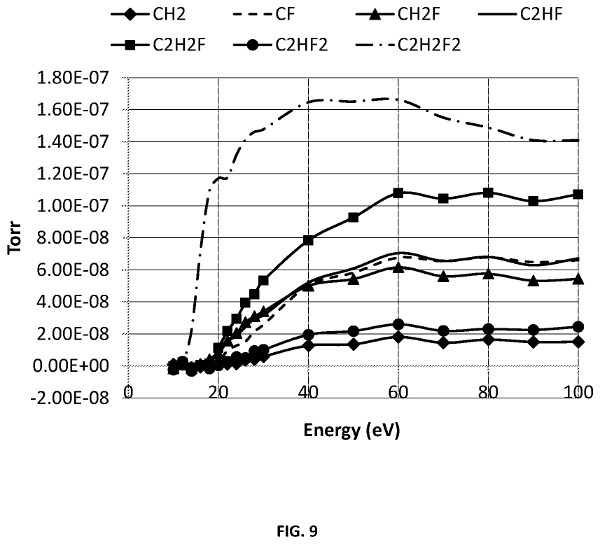

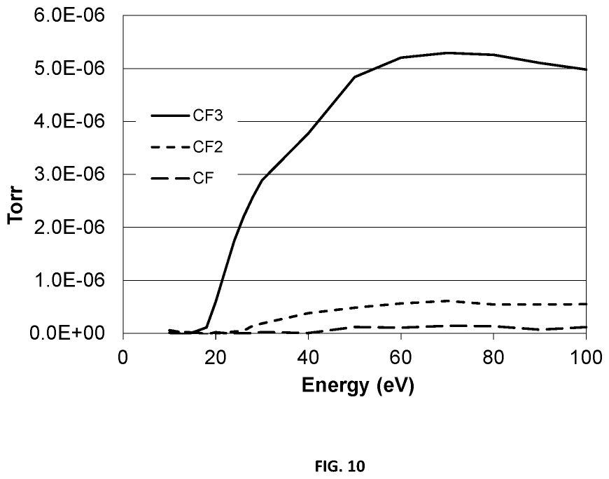

The mass spectrum of each of the gases, CF₄, CHF₃ and C₂H₂F₂ was compared using a Hiden mass spec as a function of the electron volts (eV). The spectra of pure CHF₃ was evaluated and shown in FIG. 8. The mass spectra of C₂H₂F₂ is shown in FIG. 9. The mass spectra of CF₄ is shown in FIG. 10. As shown, the mass spectra of each molecule are very different, in which the primary species of C₂H₂F₂ is a C₂H₂F species (C/F ratio is 2); the primary species of the CHF₃ is CF₃ (C/F ratio of 0.3) followed by CHF₂ (C/F ratio of 0.5). As such, C₂H₂F₂ makes larger and more carbon rich fragments that may aid in improvements in selectivity as compared to CHF₃. On the other hand, CF₄, as expected makes the primary species of CF₃ that is an etching species with very little polymerizing protection properties.

### Example 8: CH₂F₂, C₄F₈, CHF₃, and C₂H₂F₂ Deposition

The deposition rate of different fluorocarbon gases were compared by flowing the gases into a 200 mm CCP plasma etch tool at 15 sccm along with Ar at 250 sccm and a plasma source power of 750W and no bias power. No O₂ was flowed into the etch tool. As shown in Table 4, C₂H₂F₂ provides increased polymer deposition rate which may be beneficial for sidewall protection in patterning processes. It also shows based on the data shown in the previous examples that the addition of N₂ for controlling the polymerization of C₂H₂F₂ was very effective to overcome the increased polymer deposition rate as compared to CHF₃.

TABLE 4

| Gas | Deposition rate (nm/min) |
|---|---|
| CHF₃ | 40 |
| CH₂F₂ | 65 |
| C₄F₈ | 23 |
| C₂H₂F₂ | 80 |

### Example 9: Etching Rate of SiO₂, Low-k and TiN using C₂H₂F₂

The etching rate of SiO₂, low-k and TiN were evaluated using a 300 mm CCP plasma etch tool under different temperatures, pressure, plasma powers, and Ar/N₂ flow ratio. Table 5 shows the conditions and results for the three experiments. As shown, low-k etches somewhat are faster than SiO₂ etches, resulting in a higher selectivity of etch low-k to TiN mask material. Therefore, SiO₂ is a good representative film for the variety of low-k commercially available films. Also, the etching rates may depend highly on temperature and plasma powers.

TABLE 5

| | | | | | | | | Etch | Etch | | | |
|---|---|---|---|---|---|---|---|---|---|---|---|---|
| | | | Source | Bias | | | | rate | rate | Etch | Selectivity | Selectivity |
| | Temp | Pressure | Power | Power | | | | SiO₂ | Low-k | rate TiN | SiO₂:TiN | low-k:TiN |
| Experiment | (° C.) | (mTorr) | (W) | (W) | C₂H₂F₂ | N₂ | Ar | (nm/min) | (nm/min) | (nm/min) | (nm/min) | (nm/min) |
| 1 | 20 | 5 | 2000 | 500 | 15 | 105 | 0 | 93 | 161 | 9 | 10 | 18 |
| 2 | 60 | 5 | 500 | 500 | 15 | 52.5 | 52.5 | 57 | 105 | 10 | 6 | 11 |
| 3 | 20 | 25 | 2000 | 500 | 15 | 52.5 | 52.5 | 104 | 201 | 10 | 11 | 20 |

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. An etching method for forming a structure by selectively etching one or more dielectric films in a substrate using a patterned mask layer deposited on top of the one or more dielectric films, the method comprising:
mounting the substrate in a reaction chamber;
introducing an etching gas containing C₂H₂F₂ into the reaction chamber;
converting the etching gas to a plasma; and
allowing an etching reaction to proceed between the plasma and the one or more dielectric films so that the one or more dielectric films are selectively etched versus the patterned mask layer to form the structure.

2. The method of claim 1, further comprising
adding one or more hydrofluorocarbon or fluorocarbon etching gases to C₂H₂F₂, wherein the one or more fluorocarbon etching gases are selected from CF₄, C₂F₆, C₃F₈, C₄F₆, C₄F₈, C₂F₄, C₃F₆, C₄F₁₀, C₅F₈, or C₆F₆, C₇F₁₄, C₇F₁₆, or C₈F₁₆, wherein the one or more hydrofluorocarbon etching gases are C₁-C₈ hydrofluorocarbon CₓF_{y}H_{z} molecules, where x, y and z are integers, 1≤x≤8, selected from CHF₃, CH₂F₂, CH₃F, C₂HF₅, C₂H₅F, C₂H₅F, C₃H₇F, C₃H₂F₆, C₃H₂F₄, C₃H₂F₆, C₃H₄F₂, C₄H₂F₆, C₄H₃F₇, C₅F₁₀, C₅HF₇, or combination thereof.

3. The method of claim 1, further comprising
adding an additive to C₂H₂F₂, wherein the additive is selected from H₂, SF₆, NF₃, NH₃, Cl₂, BCl₃, BF₃, Br₂, F₂, FNO, FNO₃, HBr, HCl, HI, IF₅, IF₇, or HF.

4. The method of claim 1, further comprising
adding a co-reactant to C₂H₂F₂, the co-reactant is an inert gas selected from Ar, Kr, Xe, Ne, N₂, He or combination thereof.

5. The method of claim 1, further comprising
adding a co-reactant N₂ to C₂H₂F₂.

6. The method of claim 1, wherein C₂H₂F₂ is an isomer of C₂H₂F₂ with CAS No.: 75-38-7.

7. The method of claim 1, wherein C₂H₂F₂ is an isomer of C₂H₂F₂ with CAS No.: 1630-78-0.

8. The method of claim 1, wherein C₂H₂F₂ is an isomer of C₂H₂F₂ with CAS No.: 1630-77-9.

9. The method of claim 1, wherein C₂H₂F₂ is an isomer of C₂H₂F₂ with CAS No.: 1691-13-0.

10. The method of claim 1, wherein the one or more dielectric films are SiO₂ and SiCOH films.

11. The method of claim 1, wherein CO₂ equivalent emissions from the reaction chamber is at least 10% lower than that of using CF₄ as an etching gas.

12. An etching method for forming a structure with lower CO₂ equivalent emission by selectively etching one or more dielectric films in a substrate using a patterned mask layer deposited on top of the one or more dielectric films, the method comprising:
mounting the substrate in a reaction chamber;
introducing an etching gas containing C₂H₂F₂ into the reaction chamber;
converting the etching gas to a plasma; and
allowing an etching reaction to proceed between the plasma and the one or more dielectric films so that the one or more dielectric films are selectively etched versus the patterned mask layer to form the structure,
wherein CO₂ equivalent emissions from the reaction chamber is at least 10% lower than that of using CF₄ as an etching gas.

13. The method of claim 12, further comprising
adding one or more hydrofluorocarbon or fluorocarbon etching gases to the etching gas C₂H₂F₂, wherein the one or more fluorocarbon etching gases are selected from CF₄, C₂F₆, C₃F₈, C₄F₆, C₄F₈, C₂F₄, C₃F₆, C₄F₁₀, C₅F₈, C₆F₆, C₇F₁₄, C₇F₁₆, or C₈F₁₆, wherein the one or more hydrofluorocarbon etching gases are C₁-C₈ hydrofluorocarbon CₓF_{y}H_{z} molecules, where x, y and z are integers, 1≤x≤8, selected from CHF₃, CH₂F₂, CH₃F, C₂HF₅, C₂H₅F, C₂H₅F, C₃H₇F, C₃H₂F₆, C₃H₂F₄, C₃H₂F₆, C₃H₄F₂, C₄H₂F₆, C₄H₃F₇, C₅F₁₀, C₅HF₇, or combination thereof.

14. The method of claim 12, further comprising
adding an additive to C₂H₂F₂, wherein the additive is selected from H₂, SF₆, NF₃, NH₃, Cl₂, BCl₃, BF₃, Br₂, F₂, FNO, FNO₃, HBr, HCl, HI, IF₅, IF₇, or HF.

15. The method of claim 12, further comprising
adding a co-reactant to C₂H₂F₂, the co-reactant is an inert gas selected from Ar, Kr, Xe, Ne, N₂, He or combination thereof.

16. The method of claim 12, wherein C₂H₂F₂ is an isomer of C₂H₂F₂ with CAS No.: 75-38-7.

17. An etching method for forming a structure by selectively etching one or more dielectric films in a substrate using a patterned mask layer deposited on top of the one or more dielectric films, the method comprising:
mounting the substrate in a reaction chamber;
introducing an etching composition including a gas mixture of C₂H₂F₂ and an inert gas into the reaction chamber;
converting the etching composition to a plasma; and
allowing an etching reaction to proceed between the plasma and the one or more dielectric films so that the one or more dielectric films are selectively etched versus the patterned mask layer to form the structure,
wherein the temperature of the substrate ranges from −20 to 300° C.

18. The method of claim 17, wherein the inert gas is selected from Ar, Kr, Xe, No, N₂, He or combinations thereof.

19. The method of claim 17, wherein the inert gas is selected from N₂, Ar or a combination of both with any ratios of each ranging from 0-100%.

20. The method of claim 17, wherein C₂H₂F₂ is an isomer of C₂H₂F₂ with CAS No.: 75-38-7.
